(19) United States
(12) Patent Application Publication
(10) Pub. No.: US 2025/0208195 A1
(43) Pub. Date: Jun. 26, 2025

(54) METHOD AND APPARATUS TO SELECT A PORTION OF SERIAL TEST DATA RECEIVED FROM AN INTEGRATED CIRCUIT TO CAPTURE DURING TEST OF THE INTEGRATED CIRCUIT

(71) Applicant: Intel Corporation, Santa Clara, CA (US)

(72) Inventors: Shelby G. ROLLINS, Hillsboro, OR (US); Sundar V. PATHY, Chandler, AZ (US); James NEEB, Gilbert, AZ (US); Nathan S. BLACKWELL, Hillsboro, OR (US); Dhruva PATIL, Beaverton, OR (US)

(21) Appl. No.: 18/395,281

(22) Filed: Dec. 22, 2023

(51) Int. Cl. G01R 31/28

(52) U.S. Cl. CPC G01R 31/2834

(57) ABSTRACT

A test pattern syntax allows cycles of interest for a device to be tagged as serial protocol data sources during test of the integrated circuit in semiconductor automatic test equipment (ATE). A test pattern syntax is used to tag serial bits of interest. Metadata (from serial capture control contents) in combination with the tagged serial bits of interest received during the test of the integrated circuit is used to identify data in the tagged serial bits of interest. Data in the with tagged serial bits of interest is sent to other location(s) in the automated test equipment. The data in the tagged serial bits of interest can be used for real time decisions (such as thermal control) or plotted in a Graphical user interface (GUI) during test of the integrated circuit.

### BACKGROUND

Semiconductor Automatic Test Equipment (ATE) performs tests on a device that is typically referred to as a device under test (DUT) using automation to perform tests and evaluate the test results. The semiconductor ATE can test and diagnose faults on semiconductor devices including integrated circuits.

The semiconductor ATE can test packaged semiconductor devices or wafers. The semiconductor ATE typically interfaces with an automated placement tool (handler) that physically places the DUT on an interface test adapter (ITA) or “fixture” so that it can be tested.

The semiconductor ATE includes a main controller (for example, a computer) and a channel card that interfaces with the DUT. The DUT is physically connected to the semiconductor ATE through the interface test adapter (ITA).

An integrated circuit typically has a JTAG (Joint Test Action Group) port. JTAG is used to access sub-blocks/modules in the integrated circuit. The JTAG port is an industry standard interface that implements a serial communications interface to provide access to a set of test registers in the integrated circuit. Internal monitoring capabilities (for example, temperature, voltage and current) in the integrated circuit are accessible via the JTAG port.

The Institute of Electrical and Electronics Engineers (IEEE) 1149.1 Standard JTAG port uses four pins and one optional pin on the integrated circuit. The four pins are TDI (Test Data In), TDO (Test Data Out), TCK (Test Clock) and TMS (Test Mode Select). The optional pin is TRST (Test Reset). The clock input is at the TCK pin. Data is written and read serially via the JTAG port with one bit of data transferred in from TDI, and out to TDO serially per TCK rising clock edge.

Modules in the integrated circuits expose test access ports (TAPs). A host communicates with the TAPs via the JTAG port that uses four pins and one optional pin by manipulating TMS and TDI in conjunction with TCK, and reading results through TDO. Each TAP has one instruction register (IR) and multiple data registers (DR). The number of bits in the data registers varies between TAPs. The data registers are combined through TDI and TDO to form a large shift register. All information (instructions, test data, and test results) is communicated in a serial format.

### BRIEF DESCRIPTION OF DRAWINGS

Various examples in accordance with the present disclosure will be described with reference to the drawings, in which:

FIG. 1 is a block diagram of an example of a system to test an integrated circuit;

FIG. 2 is a block diagram illustrating the Joint Test Action Group (JTAG) serial communications interface between the channel card and the DUT;

FIG. 3 is a block diagram illustrating the interface between the resource/thermal card and the channel card in the ATE to perform serial capture streaming;

FIG. 4 is a block diagram illustrating the circuitry in the Resource/Thermal card to perform serial capture streaming;

FIG. 5 illustrates a pattern flow from the DUT to the channel card that includes Serial Capture Streaming Digital Temperature Sensor reads interleaved with test content patterns;

FIG. 6 is a flowgraph illustrating a method performed in the semiconductor ATE to capture a portion of serial test data received from an integrated circuit during test of the integrated circuit; and

FIG. 7 illustrates a block diagram of an example of an integrated circuit that may have one or more cores, an integrated memory controller and a JTAG port.

### DETAILED DESCRIPTION

Automated test equipment (ATE) used to test integrated circuits uses dense data structures called ‘test patterns’ to deliver test content to the integrated circuit (also referred to as a device under test (DUT)). The test patterns are delivered over standard electrical interfaces to the integrated circuit, for example via an IEEE 1149.1 JTAG port. The received test patterns are used in the integrated circuit to derive quality metrics and verify functionality of the integrated circuit.

The integrated circuit includes sensor information and other stateful information that can aid in execution or evaluations during the testing of the integrated circuit that are not available until after completion of the test. Software post flow processing, for example, parsing results of the testing of the integrated circuit returned to the ATE is very time consuming because arbitrary data is captured in a bulk storage fashion requiring a large software overhead and processing time to interpret the data. Real time data interpretation is not possible during execution of the test due to the overhead involved.

Instead of parsing results of the test of the integrated circuit after completion of the test, a pattern syntax allows cycles of interest for a device to be tagged as serial protocol data sources during the test of the integrated circuit. A test pattern syntax is used to tag serial bits of interest. Metadata (from serial capture control contents) in combination with the tagged serial bits of interest received during the test of the integrated circuit is used to identify data in the tagged serial bits of interest. The metadata and tagged serial bits of interest are forwarded to a resource/thermal controller in the automated test equipment. The data in the tagged serial bits of interest can be used for real time decisions during the test of the integrated circuit (for example, modulating the amount of power and/or cooling liquid applied to the integrated circuit to control the temperature of the integrated circuit), sent to higher level software for use by a test program (for example, the tagged serial bits of interest are a temperature value which is less than the program set point for the integrated circuit, the test program to continue to heat the integrated circuit), logged, or plotted in a graphical user interface (GUI) during the test of the integrated circuit. Standard use case examples include IEEE 1149.1 register reads, Analog to Digital converter (ADC) sample measurements, and integrated circuit temperature reads.

Serial Capture Streaming (SCS) provides Serial Capture Control (SCC) and Serial Capture Enable (SCE) pattern syntax controls. For example, SCS allows polling Phase Lock Loop (PLL) lock status in a tester pattern loop to be performed and plotted on a GUI in real time alongside of power supply rails to debug DUT initialization sequences. For example, SCS allows use of specific digital temperature sensor(s) (DTS) on the DUT for DUT thermal control in the ATE during test of the DUT.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

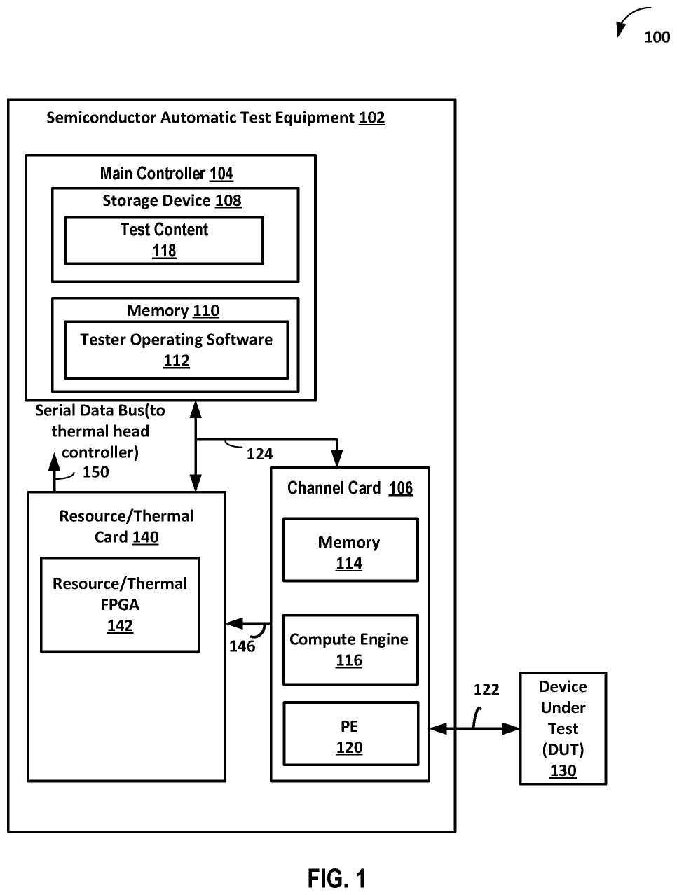

FIG. 1 is a block diagram of an example of a semiconductor Automatic Test Equipment system 100 to test a Device Under Test (DUT) 130. In the example shown the DUT 130 is an integrated circuit. Examples of integrated circuits include a processor, a System-on-Chip (SoC), a Central Processing Unit (CPU), a Graphics Processing Unit (GPU), and a Field Programmable Gate Array (FPGA). The semiconductor Automatic Test Equipment system 100 includes semiconductor automatic test equipment 102 that includes a main controller 104, a channel card 106 and a resource/thermal card 140.

The main controller 104 includes a storage device 108 to store test content 118 and memory 110 to store tester operating software.

The channel card 106 includes a memory 114, a compute engine 116 and pin electronics (PE) 120. Examples of a compute engine 116 include a processor, a System-on-Chip (SoC), a Central Processing Unit (CPU), a Graphics Processing Unit (GPU), a Field Programmable Gate Array (FPGA) and Application Specific Integrated Circuit (ASIC). The memory 114 is a volatile memory. Volatile memory is memory whose state (and therefore the data stored in it) is indeterminate if power is interrupted to the device. Dynamic volatile memory requires refreshing the data stored in the device to maintain state. One example of dynamic volatile memory includes DRAM (Dynamic Random Access Memory), or some variant such as Synchronous DRAM (SDRAM).

The pin electronics (PE) 120 is an integrated circuit that communicates with the DUT 130 over a standard Input/Output (I/O) bus 122, for example, Joint Test Action Group (JTAG), Peripheral Component Interconnect (PCI)-Express (PCIe), I2C, Serial Peripheral Interface (SPI), Platform Environment Control Interface (PECI), or other custom I/O buses.

The main controller 104 communicates with the channel card 106 and the resource/thermal card 140 over a backplane 124. The channel card 106 and the resource/thermal card 140 communicate over a serial FPGA to FPGA bus 146.

The tester operating software 112 accesses test content 118 from the storage device 108 and sends the test content 118 over the backplane 124 to the channel card 106 prior to start of the test of the DUT 130. The compute engine 116 stores the received test content in memory 114 and uses the test content 118 to test the DUT 130.

The test content stored in the memory 114 can include patterns (main, subroutine), a pattern list (plist) and captures. Patterns are test content that is used to stimulate the DUT 130. The patterns in conjunction with instructions are used by the compute engine 116 to run a test program. A main pattern is a main block of test vectors to be sent to the DUT 130. A subroutine pattern is another block of test vectors to the sent to the DUT 130 that can be sent multiple times via the main pattern. The pattern list (plist) is a list of main patterns. Captures is data created by the DUT 130 during the test of the DUT 130 that can be compared with expected results of the test of the DUT 130.

The pattern list is a list of test contents to be merged into a single execution flow. In an embodiment, the pattern list is an Extensible Markup Language (XML) file. XML is a file format for storing, transmitting, and reconstructing arbitrary data. The tester operating software 112 uses a single XML file that includes the total set of test content for program load.

The test content can be generated from simulation traces or functional specifications for the DUT 130 or can be manually generated. For example, the functional specifications for an integrated circuit can include an initialization sequence performed during reset of the integrated circuit that includes providing power to the integrated circuit and starting clocks in the integrated circuit.

The resource/thermal card 140 includes a resource/thermal FPGA 142 to manage the data paths (serial data stream on serial data bus 150 to send thermal ‘set points” to a thermal head controller) in an external system that has a heating/cooling system. The resource/thermal FPGA 142 also controls the temperature of the DUT 130 by sending a thermal “set point” on serial data bus 150 to the thermal head controller. The thermal “set point” is used by the thermal head controller to modulate the amount of power and/or cooling liquid applied to the DUT 130 to control the temperature of the DUT 130.

In an embodiment, there is one resource/thermal card 140, four compute engines 116 in the channel card 106 and fourteen channel cards 106 in the semiconductor automatic test equipment 102. In other embodiments there can be more than one resource/thermal card 140 in the semiconductor automatic test equipment 102.

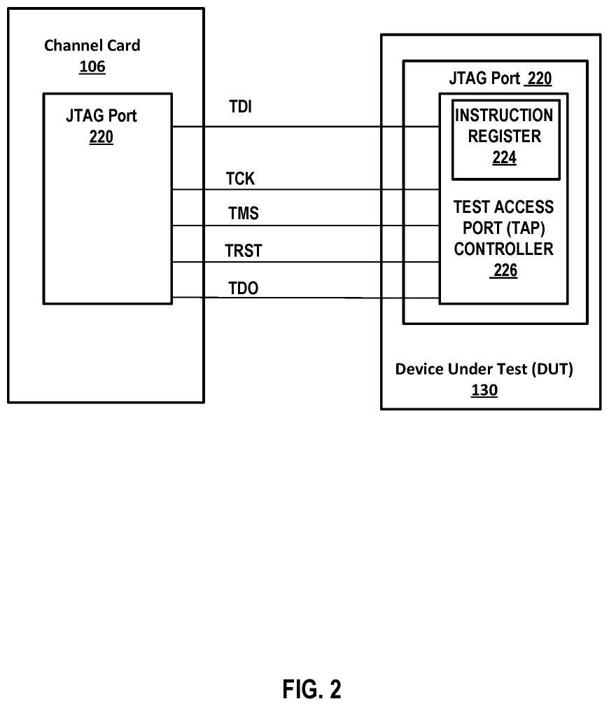

FIG. 2 is a block diagram illustrating the Joint Test Action Group (JTAG) serial communications interface between the channel card 106 and the DUT 130. The channel card 106 includes a JTAG port 220 to communicate with a JTAG port 220 in the DUT 130 over a serial communications interface.

The JTAG port 220 is an Institute of Electrical and Electronics Engineers (IEEE) 1149.1 Standard JTAG port. Data is written and read serially via the JTAG port 220 with one bit of data transferred into the DUT 130 from TDI (Test Data In), and out from the DUT 130 to TDO (Test Data Out), serially per TCK (Test Clock) rising clock edge. Data is written and read serially via the JTAG port 220 with one bit of data transferred in from TDI, and out to TDO serially per TCK rising clock edge. The JTAG port 220 includes an instruction register 224 and a Test Access Port controller 226. The JTAG protocol is a serial protocol with one bit read per clock cycle. In another embodiment, the JTAG port 220 is an Institute of Electrical and Electronics Engineers (IEEE) 1149.7 Standard JTAG port.

Data written serially to the DUT 130 via the JTAG port 220 during test of the DUT 130 includes test content. A pattern syntax in the test content allows cycles of interest of devices in the DUT 130 to be tagged as serial protocol data sources. Data read serially from the DUT 130 via the JTAG port 220 during test of the DUT 130 can include values for sensors in the DUT 130 tagged as serial protocol data sources in the pattern syntax in the test content received by the DUT 130.

The sensors can include temperature sensors, for example, digital temperature sensors. The test data can include values read from the digital temperature sensors in the DUT 130. The values read from the digital temperature sensors can be sent across the serial data bus 150 for thermal control. The serial data bus 150 can be I2C, SPI, UEI (universal equipment interface) or any other serial bus. The values read from the digital temperature sensors on the DUT 130 can be used to monitor temperatures across the DUT 130 as needed based on real time DUT sensor values to characterize test content impact on temperature of the DUT 130.

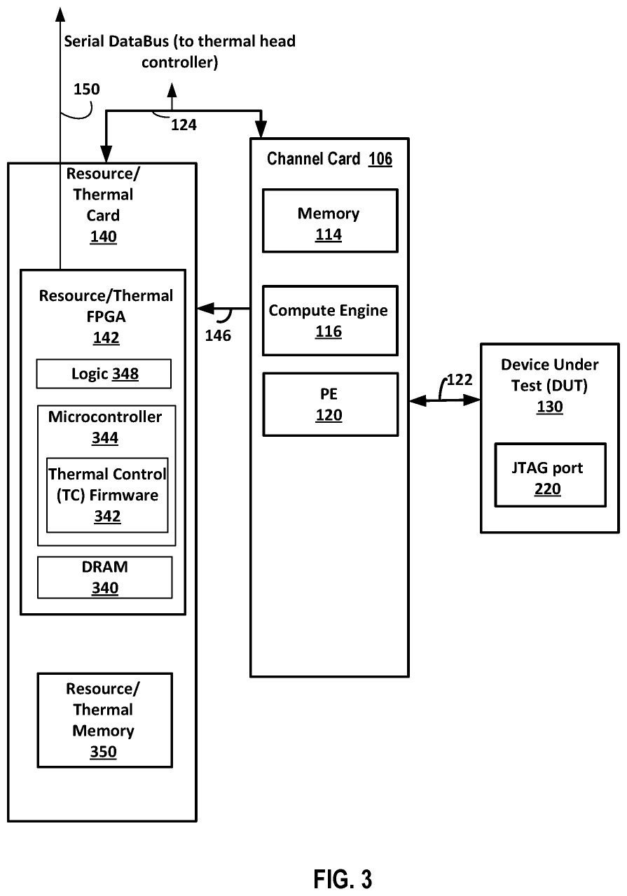

FIG. 3 is a block diagram illustrating the interface between the resource/thermal card 140 and the channel card 106 in the semiconductor automatic test equipment 102 to perform serial capture streaming. The resource/thermal card 140 includes the resource/thermal FPGA 142 and a resource/thermal memory 350.

The resource/thermal FPGA 142 includes embedded logic 348, a microcontroller 344 and random access memory 340. The embedded logic 348 includes lookup tables and other data routing logic (circuitry) to control the flow of serial capture streaming data to the microcontroller 144 or to the random access memory 340. The microcontroller 344 includes thermal control (TC) firmware 342 to manage the data paths (serial data bus 150, backplane 124) and to manage temperature control of the DUT 130. The resource/thermal control firmware 342 can also perform trim/offset calibration for temperature values and temperature conversion. The embedded logic 348 uses the metadata data in the pattern and values (for example, calibration values for temperature sensors) stored in lookup tables to route the temperature value read from the DUT 130 to the microcontroller 144. The microcontroller determines a calibrated set point and sends the calibrated set point to the thermal head controller via the serial data bus 150.

Serial capture streaming (also referred to as serial capture) captures a data stream received from the DUT 130. Serial capture streaming includes pattern syntax controls that are included in the test pattern in the data stream that are used to capture test data returned by the DUT 130. The pattern syntax controls include mid-amble patterns. A mid-amble pattern is a class of patterns to perform actions between test content in the data stream.

The pattern syntax controls include serial capture control (SCC) and serial capture enable (SCE). SCC and SCE events can be used in any class of pattern (for example, preamble, mid-amble, post-amble, standard, or any other class of pattern). SCC sets the mode of the serial captures. SCE triggers each single bit to be captured.

The compute engine 116 in the channel card 106 sends the captured test data to the resource/thermal FPGA 142 in the resource/thermal card 140 over the serial FPGA to FPGA bus 146. The embedded logic 348 in the resource/thermal FPGA 142 uses the metadata and values in the captured test data to obtain the temperature of the digital temperature sensor included in the captured test data. The resource/thermal FPGA 142 sends the temperature of the digital temperature sensor to the thermal head controller via the serial data bus 150. The resource/thermal FPGA 142 can also send the temperature of the digital temperature sensor to the main controller 104.

A serial capture stream length (SCS_LEN) for the value read from the digital temperature sensor is specified in the pattern syntax in the captured test content sent to the DUT 130. In an embodiment, the serial capture stream length can range from 8-10 bits and is selected to be 9 bits.

The endianness (Most Significant Bit (MSB) or Least Significant Bit (LSB) of the value read from the digital temperature sensor is also specified in the pattern syntax in the captured test content sent to the DUT 130. The physical pin identifier (for example, TDO pin in a JTAG port) and virtual resource identifier (for example, identifier (“name”) of the digital temperature sensor in the DUT 130) is also included in the pattern syntax in the test content sent to the DUT 130. The serial capture stream length (SCS_LEN) for values read from the digital temperature sensors can be interspersed with other vector data in the data stream received from the DUT 130.

A Plist feature in the Test Access Port allows insertion of a small pattern periodically in the Plist to read the digital temperature sensor using skip intervals.

The channel card 106 receives 8-10 bits serial capture data from the JTAG port 220 on the DUT 130. The channel card 106 combines the 8-10 bits serial capture data (payload) with serial capture control metadata in 32-bit DTS/SC trigger data. The serial capture control metadata for the digital temperature sensor can include number of bits, name (for example, temperature sensor A, JTAG register Y), physical identifiers (for example, a identifier assigned to a channel card, and pattern level (for example, virtual name, endianness, length of the payload)). The channel card 106 sends the 32-bit DTS/SC trigger data to the resource/thermal FPGA 142.

The random access memory (RAM) 340 stores a snapshot of the 32-bit DTS/SCS trigger data received from the channel card 106 per indexable serial capture sensor in the DUT 130. In an embodiment, the random access memory 340 also stores the source of the 32-bit DTS/SCS trigger data, for example, channel card (slot), FPGA in the channel card, pin (channel number in the channel card (slot) and SCS index (virtual name and pin identifier).

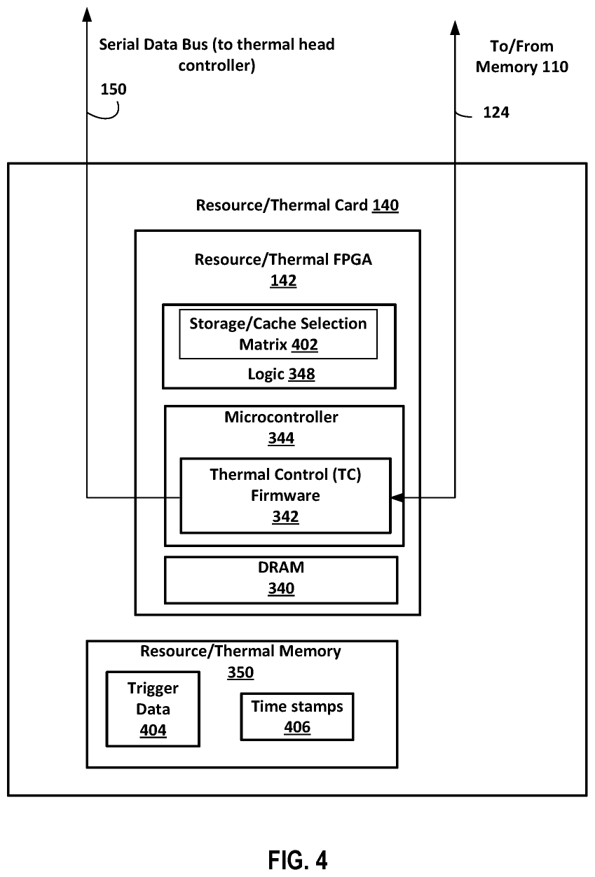

FIG. 4 is a block diagram illustrating the circuitry in the Resource/Thermal card 140 to perform serial capture streaming. The circuitry includes resource/thermal firmware 342 and storage/cache selection matrix 402. In an embodiment the resource/thermal memory 350 is a 2 GigaByte (2GiB) DRAM to store 32-bits of DTS/SC trigger data 404 and a microsecond (μs) timestamp 406 for logging and streaming to a Graphical User Interface (GUI).

The 32-bit DTS/SC trigger data 404 is received from the channel card 106 via the serial FPGA to FPGA bus 146. The 32-bit DTS/SC trigger data 404 is sorted by the resource identifier that performed the capture. Time sampling applies a serial capture control data time (timestamp 406) to synchronously align the 32-bit DTS/SC trigger data 404 with the digital temperature sensor captures. After the 32-bit DTS/SC trigger data 404 has been interpreted, it is sent via serial data bus 150 to the thermal head controller and is also sent to the main controller 104 to be stored in a shared memory buffer in memory 110 in the main controller 104. The 32-bit DTS/SC trigger data 404 stored in the shared memory buffer is used for logging and streaming to a Graphical User Interface (GUI).

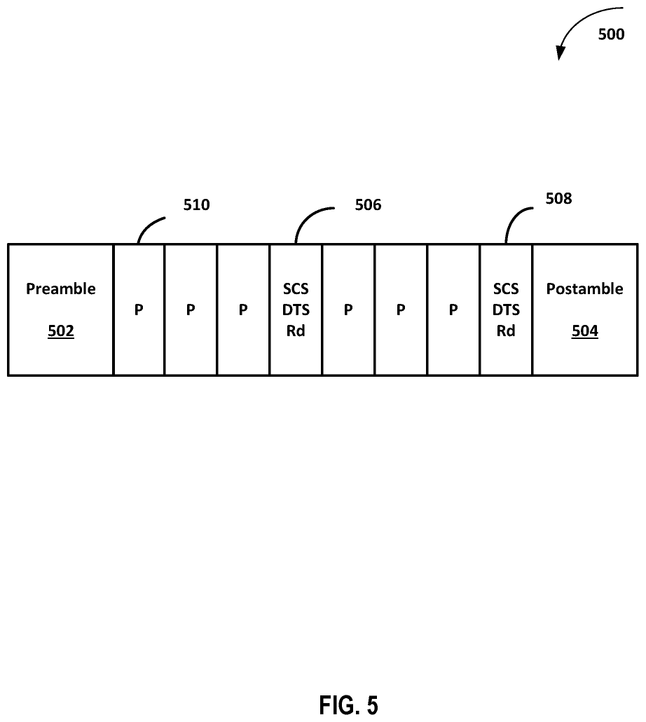

FIG. 5 illustrates a pattern flow 500 from the DUT 130 to the channel card 106 that includes Serial Capture Streaming Digital Temperature Sensor reads interleaved with test content patterns. The pattern flow 500 includes a preamble 502 and a post amble 504. The preamble 502 includes test setup pattern sequences for the DUT 130. The post amble 504 includes test end pattern sequences for the DUT 130.

A first Serial Capture Streaming Digital Temperature Sensor read 506 and a second Serial Capture Streaming Digital Temperature Sensor read 508 are interleaved with test content patterns (P) 510.

An embodiment has been described for a digital temperature sensor in the DUT.

Another example is PLL lock. A JTAG register in the DUT 130 can be marked for SCS capture to obtain the status of the PLL lock for a PLL in the DUT 130.

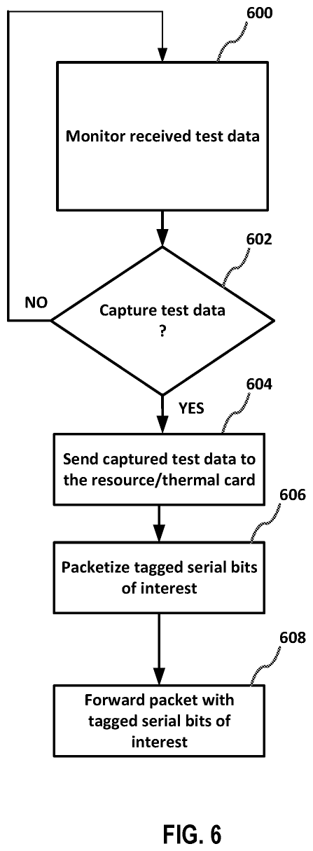

FIG. 6 is a flowgraph illustrating a method performed in the semiconductor ATE to capture a portion of serial test data received from an integrated circuit during test of the integrated circuit.

At block 600, during the test of the DUT 130, the compute engine 116 in the channel card 106 monitors test data received from the DUT 130.

At block 602, if the compute engine 116 detects capture test data, processing continues with block 604. If not, processing continues with block 600 to continue to monitor test data received from the DUT 130.

At block 604, the compute engine 116 in the channel card 106 sends the capture test data to the resource/thermal FPGA 142 in the resource/thermal card 140 over the serial FPGA to FPGA bus 146. Processing continues with block 606.

At block 606, the capture test data includes metadata (from serial capture control contents) in combination with the tagged serial bits of interest. The resource/thermal FPGA 142 uses the metadata to identify data in the tagged serial bits of interest, the source (channel) and user name associated with the tagged serial bits of interest and determine where to forward the data in the tagged serial bits of interest. Processing continues with block 608.

At block 608, the resource/thermal FPGA 142 forwards the data in the tagged serial bits of interest to other locations in the semiconductor automatic test equipment 102.

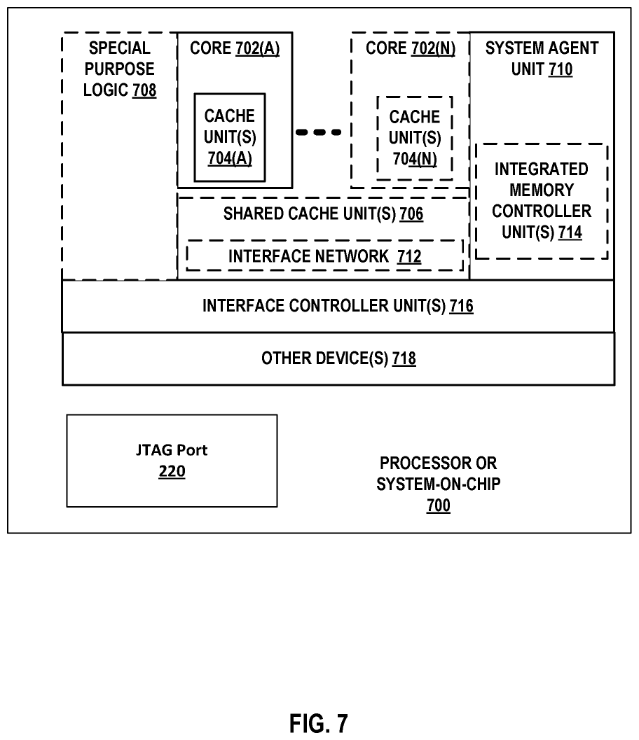

FIG. 7 illustrates a block diagram of an example integrated circuit that may have one or more cores, an integrated memory controller and a JTAG port 220. The integrated circuit can be a System on Chip (SoC) or a processor 700 that includes different components (hardware elements), also called “blocks” or subsystems.

The solid lined boxes illustrate a processor 700 with a single core 702(A), system agent unit circuitry 710, and a set of one or more interface controller unit(s) circuitry 716, while the optional addition of the dashed lined boxes illustrates an alternative processor 700 with multiple cores 702(A)-(N), a set of one or more integrated memory controller unit(s) circuitry 714 in the system agent unit circuitry 710, and special purpose logic 708, as well as a set of one or more interface controller units circuitry 716.

Thus, different implementations of the processor 700 may include: 1) a CPU with the special purpose logic 708 being integrated graphics and/or scientific (throughput) logic (which may include one or more cores, not shown), and the cores 702(A)-(N) being one or more general purpose cores (e.g., general purpose in-order cores, general purpose out-of-order cores, or a combination of the two); 2) a coprocessor with the cores 702(A)-(N) being a large number of special purpose cores intended primarily for graphics and/or scientific (throughput); and 3) a coprocessor with the cores 702(A)-(N) being a large number of general purpose in-order cores. Thus, the processor 700 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 700 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 704(A)-(N) within the cores 702(A)-(N), a set of one or more shared cache unit(s) circuitry 706, and external memory (not shown) coupled to the set of integrated memory controller unit(s) circuitry 714. The set of one or more shared cache unit(s) circuitry 706 may include one or more mid-level caches, such as level 2 (L2), level 3 (L3), level 4 (L4), or other levels of cache, such as a last level cache (LLC), and/or combinations thereof. While in some examples interface network circuitry 712 (e.g., a ring interconnect) interfaces the special purpose logic 708 (e.g., integrated graphics logic), the set of shared cache unit(s) circuitry 706, and the system agent unit circuitry 710, alternative examples use any number of well-known techniques for interfacing such units. In some examples, coherency is maintained between one or more of the shared cache unit(s) circuitry 706 and cores 702(A)-(N). In some examples, interface controller units circuitry 716 couple the cores 702 to one or more other devices 718 such as one or more I/O devices, storage, one or more communication devices (e.g., wireless networking, wired networking, etc.), etc.

In some examples, one or more of the cores 702(A)-(N) are capable of multi-threading. The system agent unit circuitry 710 includes those components coordinating and operating cores 702(A)-(N). The system agent unit circuitry 710 may include, for example, power control unit (PCU) circuitry and/or display unit circuitry (not shown). The PCU may be or may include logic and components needed for regulating the power state of the cores 702(A)-(N) and/or the special purpose logic 708 (e.g., integrated graphics logic). The display unit circuitry is for driving one or more externally connected displays.

The cores 702(A)-(N) may be homogenous in terms of instruction set architecture (ISA). Alternatively, the cores 702(A)-(N) may be heterogeneous in terms of ISA; that is, a subset of the cores 702(A)-(N) may be capable of executing an ISA, while other cores may be capable of executing only a subset of that ISA or another ISA.

Modules (for example, Voltage droop monitors and Temperature sensors) in the processor 700 expose test access ports (TAPs). A host communicates with the TAPs via the JTAG port 220 by manipulating Test Mode Select (TMS) and TDI in conjunction with TCK, and reading results through TDO. Each TAP has one instruction register (IR) and multiple data registers (DR). The number of bits in the data registers varies between TAPs. The data registers are combined through TDI and TDO to form a large shift register. All information (instructions, test data, and test results) is communicated in a serial format.

While various embodiments described herein use the term System-on-a-Chip or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Program code may be applied to input information to perform the functions described herein and generate output information. The output information may be applied to one or more output devices, in known fashion. For purposes of this application, a processing system includes any system that has a processor, such as, for example, a digital signal processor (DSP), a microcontroller, an application specific integrated circuit (ASIC), a field programmable gate array (FPGA), a microprocessor, or any combination thereof.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

Examples of the mechanisms disclosed herein may be implemented in hardware, software, firmware, or a combination of such implementation approaches. Examples may be implemented as computer programs or program code executing on programmable systems comprising at least one processor, a storage system (including volatile and non-volatile memory and/or storage elements), at least one input device, and at least one output device.

One or more aspects of at least one example may be implemented by representative instructions stored on a machine-readable medium which represents various logic within the processor, which when read by a machine causes the machine to fabricate logic to perform the techniques described herein. Such representations, known as “intellectual property (IP) cores” may be stored on a tangible, machine readable medium and supplied to various customers or manufacturing facilities to load into the fabrication machines that make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, examples also include non-transitory, tangible machine-readable media containing instructions or containing design data, such as Hardware Description Language (HDL), which defines structures, circuits, apparatuses, processors and/or system features described herein. Such examples may also be referred to as program products.

In some cases, an instruction converter may be used to convert an instruction from a source instruction set architecture to a target instruction set architecture. For example, the instruction converter may translate (e.g., using static binary translation, dynamic binary translation including dynamic compilation), morph, emulate, or otherwise convert an instruction to one or more other instructions to be processed by the core. The instruction converter may be implemented in software, hardware, firmware, or a combination thereof. The instruction converter may be on processor, off processor, or part on and part off processor.

References to “one example,” “an example,” etc., indicate that the example described may include a particular feature, structure, or characteristic, but every example may not necessarily include the particular feature, structure, or characteristic. Moreover, such phrases are not necessarily referring to the same example. Further, when a particular feature, structure, or characteristic is described in connection with an example, it is submitted that it is within the knowledge of one skilled in the art to affect such feature, structure, or characteristic in connection with other examples whether or not explicitly described.

Moreover, in the various examples described above, unless specifically noted otherwise, disjunctive language such as the phrase “at least one of A, B, or C” or “A, B, and/or C” is intended to be understood to mean either A, B, or C, or any combination thereof (i.e. A and B, A and C, B and C, and A, B and C).

The specification and drawings are, accordingly, to be regarded in an illustrative rather than a restrictive sense. It will, however, be evident that various modifications and changes may be made thereunto without departing from the broader spirit and scope of the disclosure as set forth in the claims.

### Examples

Illustrative examples of the technologies disclosed herein are provided below. An embodiment of the technologies may include any one or more, and any combination of, the examples described below.
Example 1 is a semiconductor Automatic Test Equipment (ATE) system comprising a controller a channel card and a thermal card. The controller comprising a storage device to store a test content to test a device under test. The channel card communicatively coupled to the controller. The channel card to load the test content to be received from the controller in the device under test. The device under test to be communicatively coupled to the channel card. The test content to be used to test the device under test. The test content including serial protocol data sources interleaved with other test content. The thermal card communicatively coupled to the channel card. The channel card to forward tagged serial bits of interest received from the device under test for the serial protocol data sources to the thermal card during the test of the device under test. The thermal card to identify data in the tagged serial bits of interest and to send the data in the tagged serial bits of interest to other locations in the semiconductor automatic test equipment system to be used during the test of the device under test.
Example 2 includes the system of Example 1, optionally the tagged serial bits of interest include data to be read from a sensor in the device under test and metadata associated with the data read from the sensor.
Example 3 includes the system of Example 2, optionally the sensor is a digital temperature sensor. The thermal card to route the data in the tagged serial bits of interest to a thermal head controller for use during the test of the device under test.
Example 4 includes the system of Example 1, optionally the device under test is to be communicatively coupled to a JTAG port in the channel card.
Example 5 includes the system of Example 1, optionally the channel card includes a compute engine, the compute engine to load the test content in the device under test.
Example 6 includes the system of Example 1, optionally the compute engine is a Field Programmable Gate Array (FPGA), a processor, a System-on-Chip (SoC), a Graphics Processing Unit (GPU) or an Application Specific Integrated Circuit (ASIC).
Example 7 includes the system of Example 1, optionally the device under test is an integrated circuit.
Example 8 is an apparatus comprising a channel card and a thermal card. The channel card communicatively coupled to a controller. The channel card to load the test content to be received from the controller in the device under test. The device under test to be communicatively coupled to the channel card. The test content to be used to test the device under test. The test content including serial protocol data sources interleaved with other test content. The thermal card communicatively coupled to the channel card. The channel card to forward tagged serial bits of interest received from the device under test for the serial protocol data sources to the thermal card during the test of the device under test. The thermal card to identify data in the tagged serial bits of interest and to send the data in the tagged serial bits of interest to other locations in the apparatus to be used during the test of the device under test.
Example 9 includes the apparatus of Example 8, optionally the tagged serial bits of interest include data to be read from a sensor in the device under test and metadata associated with the data read from the sensor.
Example 10 includes the apparatus of Example 9, optionally the sensor is a digital temperature sensor. The thermal card to route the data in the tagged serial bits of interest to a thermal head controller for use during the test of the device under test.
Example 11 includes the apparatus of Example 8, optionally the device under test to be communicatively coupled to a JTAG port in the channel card.
Example 12 includes the apparatus of Example 8, optionally the channel card includes a compute engine, the compute engine to load the test content in the device under test.
Example 13 includes the apparatus of Example 12, optionally the compute engine is a Field Programmable Gate Array (FPGA), a processor, a System-on-Chip (SoC), a Graphics Processing Unit (GPU) or an Application Specific Integrated Circuit (ASIC).
Example 14 includes the apparatus of Example 8, optionally the device under test is an integrated circuit.
Example 15 is a method comprising storing test content to test a device under test in a storage device in a controller in a semiconductor automatic test equipment system. The method also includes loading, by a channel card, communicatively coupled to the controller, the test content to be received from the controller in the device under test, the device under test to be communicatively coupled to the channel card, the test content to be used to test the device under test, the test content including serial protocol data sources interleaved with other test content. The method also includes forwarding, by a thermal card communicatively coupled to the channel card, tagged serial bits of interest to be received from the device under test for the serial protocol data sources to the thermal card during the test of the device under test, the thermal card to identify data in the tagged serial bits of interest. The method also includes sending the data in the tagged serial bits of interest to other locations in the semiconductor automatic test equipment system to be used during the test of the device under test.
Example 16 includes the method of Example 15, optionally the tagged serial bits of interest to include data read from a sensor in the device under test and metadata associated with the data read from the sensor.
Example 17 includes the method of Example 16, optionally the sensor is a digital temperature sensor. The thermal card to route the data in the tagged serial bits of interest to a thermal head controller for use during the test of the device under test.
Example 18 includes the method of Example 15, optionally the device under test to be communicatively coupled to a JTAG port in the channel card.
Example 19 includes the method of Example 15, optionally the channel card includes a compute engine, the compute engine to load the test content in the device under test.
Example 20 includes the method of Example 15, optionally the device under test is an integrated circuit.
Example 21 is at least one machine readable medium that includes a plurality of instructions that in response to being executed by a system can cause the system to carry out a method according to any one of examples 15 to 20.
Example 22 is an apparatus that includes means for performing the methods of any one of examples 15 to 20.

What is claimed is:

1. A semiconductor automatic test equipment system comprising:
a controller, the controller comprising a storage device to store a test content to test a device under test; and
a channel card communicatively coupled to the controller, the channel card to load the test content to be received from the controller in the device under test, the device under test to be communicatively coupled to the channel card, the test content used to test the device under test, the test content including serial protocol data sources interleaved with other test content; and
a thermal card communicatively coupled to the channel card, the channel card to forward tagged serial bits of interest to be received from the device under test for the serial protocol data sources to the thermal card during the test of the device under test, the thermal card to identify data in the tagged serial bits of interest and to send the data in the tagged serial bits of interest to other locations in the semiconductor automatic test equipment system to be used during the test of the device under test.

2. The semiconductor automatic test equipment system of claim 1, wherein the tagged serial bits of interest include data to be read from a sensor in the device under test and metadata associated with the data read from the sensor.

3. The semiconductor automatic test equipment system of claim 2, wherein the sensor is a digital temperature sensor, the thermal card to route the data in the tagged serial bits of interest to a thermal head controller for use during the test of the device under test.

4. The semiconductor automatic test equipment system of claim 1, wherein the device under test is to be communicatively coupled to a JTAG port in the channel card.

5. The semiconductor automatic test equipment system of claim 1, wherein the channel card includes a compute engine, the compute engine to load the test content in the device under test.

6. The semiconductor automatic test equipment system of claim 5, wherein the compute engine is a Field Programmable Gate Array (FPGA), a processor, a System-on-Chip (SoC), a Graphics Processing Unit (GPU) or an Application Specific Integrated Circuit (ASIC).

7. The semiconductor automatic test equipment system of claim 1, wherein the device under test is an integrated circuit.

8. An apparatus comprising:
a channel card communicatively coupled to a controller, controller comprising a storage device to store a test content to test a device under test, the channel card to load the test content received from the controller in the device under test, the device under test to be communicatively coupled to the channel card, the test content to be used to test the device under test, the test content including serial protocol data sources interleaved with other test content; and
a thermal card communicatively coupled to the channel card, the channel card to forward tagged serial bits of interest to be received from the device under test for the serial protocol data sources to the thermal card during the test of the device under test, the thermal card to identify data in the tagged serial bits of interest and to send the data in the tagged serial bits of interest to other locations in the apparatus to be used during the test of the device under test.

9. The apparatus of claim 8, wherein the tagged serial bits of interest include data read from a sensor in the device under test and metadata associated with the data to be read from the sensor.

10. The apparatus of claim 9, wherein the sensor is a digital temperature sensor, the thermal card to route the data in the tagged serial bits of interest to a thermal head controller for use during the test of the device under test.

11. The apparatus of claim 8, wherein the device under test to be communicatively coupled to a JTAG port in the channel card.

12. The apparatus of claim 8, wherein the channel card includes a compute engine, the compute engine to load the test content in the device under test.

13. The apparatus of claim 12, wherein the compute engine is a Field Programmable Gate Array (FPGA), a processor, a System-on-Chip (SoC), a Graphics Processing Unit (GPU) or an Application Specific Integrated Circuit (ASIC).

14. The apparatus of claim 8, wherein the device under test is an integrated circuit.

15. A method comprising:
storing test content to test a device under test in a storage device in a controller in a semiconductor automatic test equipment system;
loading, by a channel card communicatively coupled to the controller, the test content received from the controller in the device under test, the device under test to be communicatively coupled to the channel card, the test content to be used to test the device under test, the test content including serial protocol data sources interleaved with other test content;
forwarding, by a thermal card communicatively coupled to the channel card, tagged serial bits of interest to be received from the device under test for the serial protocol data sources to the thermal card during the test of the device under test, the thermal card to identify data in the tagged serial bits of interest; and
sending the data in the tagged serial bits of interest to other locations in the semiconductor automatic test equipment system to be used during the test of the device under test.

16. The method of claim 15, wherein the tagged serial bits of interest include data to be read from a sensor in the device under test and metadata associated with the data read from the sensor.

17. The method of claim 16, wherein the sensor is a digital temperature sensor, the thermal card to route the data in the tagged serial bits of interest to a thermal head controller for use during the test of the device under test.

18. The method of claim 15, wherein the device under test to be communicatively coupled to a JTAG port in the channel card.

19. The method of claim 15, wherein the channel card includes a compute engine, the compute engine to load the test content in the device under test.

20. The method of claim 15, wherein the device under test is an integrated circuit.
